(19) United States
(12) Patent Application Publication
(10) Pub. No.: US 2025/0361442 A1
(43) Pub. Date: Nov. 27, 2025

(54) ETCHANT COMPOSITION

(71) Applicant: DONGJIN SEMICHEM CO., LTD., Incheon (KR)

(72) Inventors: Ga Hyeon SEO, Hwaseong-si (KR); Hyun Cheol SHIN, Hwaseong-si (KR); Dae Ro KWON, Hwaseong-si (KR); Jun Young HWANG, Hwaseong-si (KR); Kyeong Woong CHA, Hwaseong-si (KR); Sung Min KIM, Hwaseong-si (KR)

(21) Appl. No.: 19/203,788

(22) Filed: May 9, 2025

(30) Foreign Application Priority Data
May 13, 2024 (KR) 10-2024-0062566

(51) Int. Cl. C09K 13/08

(52) U.S. Cl. CPC C09K 13/08

(57) ABSTRACT

An etchant composition includes hydrogen peroxide, a carboxylic acid-based compound, a fluorine-based compound, and a nitrogen-based cyclic compound. The hydrogen peroxide is included in an amount of 0.001 to 4 wt %. Additionally or alternatively, the weight ratio between the fluorine-based compound and the nitrogen-based cyclic compound is 1:0.01 to 1:3.

### CROSS-REFERENCE TO RELATED APPLICATION

This application claims priority from Korean Patent Application No. 10-2024-0062566 filed on May 13, 2024, which is incorporated herein by reference in its entirety.

### BACKGROUND

### 1. Technical Field

The present disclosure relates to an etchant composition, and more specifically, to an etchant composition for etching a metal wiring film.

### 2. Related Art

As the field of displays that visually expresses various kinds of electrical signal information has advanced, various flat panel display devices having excellent characteristics such as a small thickness, a light weight, and low power consumption have been researched and developed.

Meanwhile, as the display area of the display device becomes larger, various wires and electrodes included in the display device need to be formed of materials with the lowest possible resistivity. To this end, various wires and electrodes in the display device may include metals.

In addition, various wires and electrodes included in the display device may be formed using a patterning process such as a photolithography process, which includes an etching process. However, when the wires or electrodes are composed of multilayer films having different properties, there is a limit to forming wires or electrodes having desired properties by the etching process.

### SUMMARY

An object of the present disclosure is to provide an etchant composition exhibiting an excellent etch profile of a metal wiring film after etching.

Another object of the present disclosure is to provide an etchant composition that may reduce damage to the upper layer of a metal wiring film, which is a multilayer film, and minimize undercut of the lower layer.

Still another object of the present disclosure is to provide a method of etching a metal wiring film using the etchant composition.

The objects to be achieved by the present disclosure are not limited to the objects mentioned above, and other objects not mentioned will be clearly understood by those skilled in the art from the following description.

To achieve the above objects, the present disclosure provides an etchant composition including hydrogen peroxide, a carboxylic acid-based compound, a fluorine-based compound, and a nitrogen-based cyclic compound. In particular, the hydrogen peroxide may be included in an amount of 0.001 to 4 wt %.

The present disclosure also provides an etchant composition including hydrogen peroxide, a carboxylic acid-based compound, a fluorine-based compound, and a nitrogen-based cyclic compound. In particular, the weight ratio between the fluorine-based compound and the nitrogen-based cyclic compound may be 1:0.01 to 1:3.

The etchant composition may include 0.1 to 5 wt % of the carboxylic acid-based compound; 0.01 to 2 wt % of the fluorine-based compound, 0.001 to 1 wt % of the nitrogen-based cyclic compound, and the balance of water.

The etchant composition may further include at least one of 1 to 5 wt % of a glycol-based compound, 0.01 to 5 wt % of a phosphate compound, 0.001 to 2 wt % of an acetate salt, or 0.001 to 1 wt % of an amino acid derivative.

The amino acid derivative may be any one selected from L-pyroglutamic acid, sodium pyrrolidone carboxylic acid, zinc pyrrolidone carboxylic acid, or any combinations thereof.

The weight ratio between the hydrogen peroxide and the fluorine-based compound may be 1:0.01 to 1:9.

The weight ratio between the hydrogen peroxide and the nitrogen-based cyclic compound may be 1:0.1 to 1:1.5.

The weight ratio between the fluorine-based compound and the nitrogen-based cyclic compound may be 1:0.01 to 1:3.

The carboxylic acid-based compound may be at least one selected from the group consisting of iminodiacetic acid, oxalic acid, acetic acid, formic acid, acrylic acid, lactic acid, amino acids, propionic acid, oleic acid, benzoic acid, salicylic acid, malic acid, and any combinations thereof.

The glycol-based compound may be at least one selected from the group consisting of ethylene glycol, diethylene glycol, triethylene glycol, polyethylene glycol, and any combinations thereof.

The phosphate compound may be at least one selected from the group consisting of ammonium monophosphate, sodium monophosphate, sodium diphosphate, ammonium diphosphate, sodium triphosphate, ammonium triphosphate, and any combinations thereof.

The acetate salt may be at least one selected from the group consisting of ammonium acetate salt, sodium acetate, potassium acetate, and any combinations thereof.

The fluorine-based compound may be at least one selected from the group consisting of ammonium bifluoride (NH₄F·HF), ammonium fluoride (NH₄F), sodium bifluoride (NaHF₂), sodium fluoride (NaF), potassium bifluoride (HF₂K), potassium fluoride (KF), hydrofluoric acid (HF), and any combinations thereof.

The nitrogen-based cyclic compound may not include alkyl and aryl groups.

The nitrogen-based cyclic compound may be at least one selected from the group consisting of benzotriazole, aminotetrazole, methyltetrazole, aminomercaptotriazole, and any combinations thereof.

The metal concentration in the etchant composition may be 500 ppm or less.

The etchant composition may be for etching a metal film, which includes at least one selected from the group consisting of copper, molybdenum, titanium, and a molybdenum-titanium alloy.

The etchant composition may be used for semiconductor packaging.

The present disclosure may provide an etchant composition exhibiting an excellent etch profile of a metal wiring film after etching.

The present disclosure may also provide an etchant composition that may reduce damage to the upper layer of a metal wiring film, which is a multilayer film, and minimize undercut of the lower layer.

The effects of the present disclosure are not limited to the effects described above, and should be understood to include all effects that can be inferred from the configuration of the present disclosure described in the detailed description and claims of the present disclosure.

### DETAILED DESCRIPTION

Hereinafter, embodiments of the present disclosure will be described in detail. However, these embodiments are presented as examples, and the present disclosure is not limited by these embodiments. Furthermore, the present disclosure is defined only by the scope of the claims set forth below. Herein, any embodiments can be implemented alone or in any combinations.

In an embodiment of the present disclosure, there is provided an etchant composition including hydrogen peroxide, a carboxylic acid-based compound, a fluorine-based compound, and a nitrogen-based cyclic compound.

In an embodiment, the etchant composition is capable of etching a metal film including at least one selected from the group consisting of copper, molybdenum, titanium, and a molybdenum-titanium alloy.

In an embodiment, the metal film may be a single-layer metal film containing copper or a multilayer film of two or more layers containing copper.

Examples of the multilayer film include a bilayer film consisting of a copper metal layer as an upper layer and a titanium metal layer as a lower layer, a bilayer film consisting of a titanium metal layer as an upper layer and a copper metal layer as a lower layer, a bilayer film consisting of a copper metal layer/molybdenum-titanium alloy layer, and a trilayer or higher multilayer film in which a copper metal layer and a titanium metal layer are alternately stacked, such as a titanium metal layer/copper metal layer/titanium metal layer or a copper metal layer/titanium metal layer/copper metal layer.

In an embodiment, the multilayer film may be a bilayer film consisting of a copper metal layer as an upper layer and a titanium metal layer as a lower layer.

In an embodiment, hydrogen peroxide may be used as an oxidizing agent for a copper metal layer and a titanium metal layer and as a main component for etching the metal layers.

The hydrogen peroxide may be included in an amount of 0.001 to 4 wt %, 0.001 to 3 wt %, 0.001 to 2 wt %, 0.001 to 1.5 wt %, 0.001 to 1.2 wt %, or 0.001 to 1 wt %, based on the total weight of the etchant composition. When the etchant composition includes hydrogen peroxide in an amount within the above range, damage to a copper metal layer as an upper layer may be reduced, and undercut of a titanium metal layer as a lower layer may be reduced.

In an embodiment, the carboxylic acid-based compound may be used as a titanium ion chelating agent that selectively oxidizes and etches a titanium metal film without etching the copper metal layer by controlling the reaction between hydrogen peroxide and titanium ions.

The carboxylic acid-based compound may include, for example, at least one selected from the group consisting of iminodiacetic acid, oxalic acid, acetic acid, formic acid, acrylic acid, lactic acid, amino acids, propionic acid, oleic acid, benzoic acid, salicylic acid, malic acid, and any combinations thereof.

In an embodiment, the carboxylic acid-based compound may include iminodiacetic acid.

The carboxylic acid-based compound may be included in an amount of 0.1 to 5 wt %, 0.1 to 4 wt %, 0.2 to 3 wt %, 0.3 to 2 wt %, or 0.5 to 2 wt %, based on the total weight of the etchant composition. When the etchant composition includes the carboxylic acid-based compound in an amount within the above range, the carboxylic acid-based compound may selectively oxidize the titanium (Ti) layer by controlling the reaction between hydrogen peroxide and titanium ions, thereby helping to improve the etching ability of the etchant composition.

In an embodiment, the fluorine-based compound may be used as an oxidizing etchant for a titanium metal layer.

The fluorine-based compound may include, for example, at least one selected from the group consisting of ammonium bifluoride (NH₄F·HF), ammonium fluoride (NH₄F), sodium bifluoride (NaHF₂), sodium fluoride (NaF), potassium bifluoride (HF₂K), potassium fluoride (KF), hydrofluoric acid (HF), and any combinations thereof.

In an embodiment, the fluorine-based compound may include ammonium bifluoride.

The fluorine-based compound may be included in an amount of 0.01 to 2 wt %, 0.04 to 2 wt %, 0.08 to 2 wt %, 0.1 to 2 wt %, or 0.5 to 1 wt %, based on the total weight of the etchant composition. When the etchant composition includes the fluorine-based compound in an amount within the above range, the etch rate may be more easily controlled.

In an embodiment, the nitrogen-based cyclic compound may be used as an etching inhibitor to slow down or decrease the etch rate of a copper metal layer and a titanium metal layer.

In an embodiment, the nitrogen-based cyclic compound may not include alkyl and aryl groups.

The nitrogen-based cyclic compound may include, for example, at least one selected from the group consisting of benzotriazole, aminotetrazole, methyltetrazole, aminomercaptotriazole, and any combinations thereof.

In an embodiment, the nitrogen-based cyclic compound may include aminotetrazole.

The nitrogen-based cyclic compound may be included in an amount of 0.001 to 1 wt %, 0.008 to 0.9 wt %, 0.01 to 0.8 wt %, 0.1 to 0.7 wt %, or 0.15 to 0.5 wt %, based on the total weight of the etchant composition. When the etchant composition includes the nitrogen-based cyclic compound in an amount within the above range, the etch rate may be more easily controlled.

In an embodiment, the weight ratio between the hydrogen peroxide and the fluorine-based compound may be 1:0.01 to 1:9, 1:0.90 to 1:7, 1:1 to 1:6, 1:1.2 to 1:5, 1:1.5 to 1:4, or 1:1.8 to 1:3.6. When the weight ratio between the hydrogen peroxide and the fluorine-based compound is within the above range, damage to a copper metal layer as an upper layer may be reduced, and undercut of a titanium metal layer as a lower layer may be reduced.

In an embodiment, the weight ratio between the hydrogen peroxide and the nitrogen-based cyclic compound may be 1:0.1 to 1:1.5, 1:0.2 to 1:1.4, 1:0.3 to 1:1.3, 1:0.4 to 1:1.2, 1:0.5 to 1:1.1, or 1:0.68 to 1:1. When the weight ratio of the hydrogen peroxide and the nitrogen-based cyclic compound is within the above range, damage to a copper metal layer as an upper layer may be reduced, and undercut of a titanium metal layer as a lower layer may be reduced.

In an embodiment, the weight ratio between the fluorine-based compound and the nitrogen-based cyclic compound may be 1:0.01 to 1:3, 1:0.05 to 1:2.7, 1:0.08 to 1:2.3, 1:0.1 to 1:2.3, 1:0.12 to 1:2.0, or 1:0.15 to 1:0.19. When the weight ratio between the fluorine-based compound and the nitrogen-based cyclic compound is within the above range, damage to a copper metal layer as an upper layer may be reduced, and undercut of a titanium metal layer as a lower layer may be reduced.

In an embodiment, the etchant composition may further include at least one of a glycol-based compound, a phosphate compound, an acetate salt compound, or an amino acid derivative.

In an embodiment, the glycol-based compound can be used as a hydrogen peroxide stabilizer for suppressing a decrease in stability and a decrease in the amount of titanium metal layer to be etched, which result from an exothermic reaction caused by the decomposition of hydrogen peroxide.

The glycol-based compound may include at least one selected from the group consisting of ethylene glycol, diethylene glycol, triethylene glycol, polyethylene glycol, and any combinations thereof.

In an embodiment, the glycol-based compound may include triethylene glycol.

The glycol-based compound may be included in an amount of 1 to 5 wt %, 1 to 4 wt %, 1 to 3 wt %, or 1 to 2 wt %, based on the total weight of the etchant composition. When the etchant composition includes the glycol-based compound in an amount within the above range, the glycol-based compound may suppress the decomposition of hydrogen peroxide that may occur when the etchant is repeatedly used, thereby ensuring the stability of the etchant.

In an embodiment, the phosphate compound may be used as an auxiliary oxidizing etchant for a titanium metal layer to prevent the etch rate from decreasing and to control the taper angle during pattern formation.

The phosphate compound may include at least one selected from the group consisting of ammonium monophosphate, sodium monophosphate, sodium diphosphate, ammonium diphosphate, sodium triphosphate, ammonium triphosphate, and any combinations thereof.

In an embodiment, the phosphate compound may include ammonium monophosphate.

The phosphate compound may be included in an amount of 0.01 to 5 wt %, 0.03 to 4 wt %, 0.05 to 3 wt %, 0.08 to 2 wt %, or 0.1 to 1 wt %, based on the total weight of the etchant composition. When the phosphate compound is included in the etchant composition in an amount within the above range, it may prevent the etch rate from decreasing and may control the taper angle, thereby helping to form a pattern.

In an embodiment, the acetate salt may be used as a as a pH regulator that may increase the pH of the etchant composition, thereby slowing down or decreasing the etch rate of a copper metal layer and increasing the etch rate of a titanium metal layer.

The acetate salt may include at least one selected from the group consisting of ammonium acetate, sodium acetate, potassium acetate, and any combinations thereof.

In an embodiment, the acetate salt may include ammonium acetate.

The acetate salt may be included in an amount of 0.001 to 2 wt %, 0.005 to 1.5 wt %, 0.008 to 1 wt %, 0.01 to 0.7 wt %, or 0.05 to 0.5 wt %, based on the total weight of the etchant composition. When the etchant composition includes the acetate salt in an amount within the above range, the acetate salt may adjust the pH of the etchant composition so that the hydrogen peroxide can more effectively etch a titanium metal layer.

In an embodiment, the amino acid derivative may be used as a bath life improver that prevents the etch rate from changing due to an increase in the cumulative number of titanium metal layers.

In an embodiment, the amino acid derivative may include a pyrrolidone derivative.

The pyrrolidone derivative may include, for example, at least one selected from the group consisting of L-pyroglutamic acid, sodium pyrrolidone carboxylic acid, zinc pyrrolidone carboxylic acid, and any combinations thereof.

In an embodiment, the amino acid derivative may include L-pyroglutamic acid.

The amino acid derivative may be included in an amount of 0.001 to 1 wt %, 0.005 to 1 wt %, 0.008 to 1 wt %, 0.01 to 1 wt %, 0.05 to 1 wt %, or 0.1 to 1 wt %, based on the total weight of the etchant composition. When the amino acid derivative is included in the etchant composition in an amount within the above range, it may improve the stability of the etchant composition, thereby increasing the bath life.

In an embodiment, the weight ratio between the hydrogen peroxide and the amino acid derivative may be 1:0.001 to 1:20, 1:0.005 to 1:15, 1:0.01 to 1:10, 1:0.05 to 1:5, or 1:0.1 to 1:2. When the weight ratio between the hydrogen peroxide and the amino acid derivative is within the above range, a high cumulative number of metal films treated with the etchant composition may be maintained.

In an embodiment, the weight ratio of the carboxylic acid-based compound and the amino acid derivative may be 1:0.002 to 1:20, 1:0.004 to 1:17, 1:0.008 to 1:14, 1:0.01 to 1:9, 1:0.08 to 1:5, or 0.2 to 2. When the weight ratio of the carboxylic acid-based compound and the amino acid derivative is within the above range, a high cumulative number of metal films treated with the etchant composition may be maintained.

In an embodiment, the etchant composition may further include the balance of water in addition to the components described above.

In an embodiment, the etchant composition may be used for semiconductor packaging.

In an embodiment, the metal concentration in the etchant composition may be 500 ppm or less. When the metal concentration in the etchant composition is within the above range, the performance and safety of the etchant composition may be maintained more stably. That is, when the metal concentration in the etchant composition is 0 ppm to 500 ppm, the etching performance and stability may be maintained, and thus the cumulative number of metal films treated with the etchant composition may increase.

In an embodiment of the present disclosure, there is provided a method for etching a metal film, which includes a step of etching a metal film (also referred to as a metal wiring film), formed on a substrate, with the above-described etchant composition.

In an embodiment, the substrate may be a glass substrate that includes silicon oxide (SiO₂) as a main component, or a substrate made of a transparent plastic material. Specifically, the substrate made of a plastic material may be a substrate made of polyethersulphone (PES), polyacrylate, polyetherimide, polyethylene naphthalate, polyethylene terephthalate, polyphenylene sulfide (PPS), polyallylate, polyimide, polycarbonate, cellulose triacetate, cellulose acetate propionate (CAP), or the like. However, the technical idea of the present disclosure is not limited thereto, and various substrates in the display and semiconductor fields may be applied.

In an embodiment, the metal film may be a single-layer metal film containing copper or a multilayer film of two or more layers containing copper.

In an embodiment, a general deposition method commonly used in the relevant technical field may be used to form the metal film.

In an embodiment, when the bilayer film consisting of the copper metal layer and the titanium metal layer is etched with the etchant composition described above, the undercut of the titanium metal layer may be 150 nm or less.

When the undercut is 150 nm or less, the contact area between an under-bump metallurgy (UBM) layer and a bump increases, and the reliability of the bump may be improved, which helps in the production of a highly integrated circuit.

In an embodiment, when a target film (metal film) is etched with the etchant composition described above, the width of the pattern to be etched may be less than 2 μm.

When the width of the pattern is less than 2 μm, it is possible to produce a microcircuit with a higher degree of integration than conventional one and embed an integrated chip (IC) into one side or both sides of the substrate, and thus integration in the form of a thin film by stacking of substrates is possible. In particular, the method of the present disclosure may be applied in the UBM process.

As used herein, the term “under-bump metallurgy (UBM) layer” means a multilayer metal layer that is formed between an electrode and a bump to facilitate adhesion and prevent diffusion into the chip because it is difficult to form solder or bumps directly on the electrodes of a semiconductor chip.

The above description has explained the technical idea of the present disclosure by way of the embodiments, and those of ordinary skill in the art to which the present disclosure pertains will be able to make various modifications and variations without departing from the essential characteristics of the present disclosure. Therefore, the embodiments disclosed in the present disclosure are not intended to limit the technical spirit of the present disclosure, but are provided for illustrative purposes, and the scope of the technical spirit of the present disclosure is not limited by these embodiments. The scope of protection of the present disclosure should be construed according to the appended claims, and all technical ideas falling within the scope thereof shall be construed as falling within the scope of the present disclosure.

### Preparation Examples and Comparative Preparation Examples: Preparation of Etchant Compositions

Etchant compositions were prepared according to the compositions shown in Tables 1 and 2 below, and the balance of water was included so that the total weight of the etchant composition was 100 wt %.

Except for Preparation Examples 5 to 16 in Table 1 below, L-pyroglutamic acid was used as an amino acid derivative.

TABLE 1

| | | Fluorine- | Nitrogen- | | Glycol- | | | |
|---|---|---|---|---|---|---|---|---|
| | Hydrogen | based | based cyclic | Carboxylic | based | | Acetate | Amino acid |
| | peroxide | compound ²⁾ | compound ³⁾ | compound ⁴⁾ | compound ⁵⁾ | Phosphate ⁶⁾ | salt ⁷⁾ | derivative ⁸⁾ |
| Preparation | 0.5 | 0.9 | 0.25 | 0.5 | 1.5 | 0.2 | 0.05 | 0.1 (L-pyroglutamic |
| Example 1 | | | | | | | | acid) |
| Preparation | 0.5 | 0.9 | 0.25 | 0.5 | 1.5 | 0.2 | 0.05 | |
| Example 2 | | | | | | | | |
| Preparation | 0.5 | 0.9 | 0.25 | 0.5 | 1.5 | 0.2 | 0.05 | |
| Example 3 | | | | | | | | |
| Preparation | 0.5 | 0.9 | 0.25 | 0.5 | 1.5 | 0.2 | 0.05 | |
| Example 4 | | | | | | | | |
| Preparation | 0.5 | 0.9 | 0.25 | 0.5 | 1.5 | 0.2 | 0.05 | 0.1 (glutamic acid) |
| Example 5 | | | | | | | | |
| Preparation | 0.5 | 0.9 | 0.25 | 0.5 | 1.5 | 0.2 | 0.05 | |
| Example 6 | | | | | | | | |
| Preparation | 0.5 | 0.9 | 0.25 | 0.5 | 1.5 | 0.2 | 0.05 | |
| Example 7 | | | | | | | | |
| Preparation | 0.5 | 0.9 | 0.25 | 0.5 | 1.5 | 0.2 | 0.05 | |
| Example 8 | | | | | | | | |
| Preparation | 0.5 | 0.9 | 0.25 | 0.5 | 1.5 | 0.2 | 0.05 | 0.1 (acetylcarnitine) |
| Example 9 | | | | | | | | |
| Preparation | 0.5 | 0.9 | 0.25 | 0.5 | 1.5 | 0.2 | 0.05 | |
| Example 10 | | | | | | | | |
| Preparation | 0.5 | 0.9 | 0.25 | 0.5 | 1.5 | 0.2 | 0.05 | |
| Example 11 | | | | | | | | |
| Preparation | 0.5 | 0.9 | 0.25 | 0.5 | 1.5 | 0.2 | 0.05 | |
| Example 12 | | | | | | | | |
| Preparation | 0.5 | 0.9 | 0.25 | 0.5 | 1.5 | 0.2 | 0.05 | 0.1 (glycocyamine) |
| Example 13 | | | | | | | | |
| Preparation | 0.5 | 0.9 | 0.25 | 0.5 | 1.5 | 0.2 | 0.05 | |
| Example 14 | | | | | | | | |
| Preparation | 0.5 | 0.9 | 0.25 | 0.5 | 1.5 | 0.2 | 0.05 | |
| Example 15 | | | | | | | | |
| Preparation | 0.5 | 0.9 | 0.25 | 0.5 | 1.5 | 0.2 | 0.05 | |
| Example 16 | | | | | | | | |
| Preparation | 0.5 | 0.9 | 0.25 | 0.5 | 1.5 | 0.2 | 0.05 | 0.001 |
| Example 17 | | | | | | | | |
| Preparation | 0.5 | 0.9 | 0.25 | 0.5 | 1.5 | 0.2 | 0.05 | 0.005 |
| Example 18 | | | | | | | | |
| Preparation | 0.5 | 0.9 | 0.25 | 0.5 | 1.5 | 0.2 | 0.05 | 0.010 |
| Example 19 | | | | | | | | |
| Preparation | 0.5 | 0.9 | 0.25 | 0.5 | 1.5 | 0.2 | 0.05 | 0.020 |
| Example 20 | | | | | | | | |
| Preparation | 0.5 | 0.9 | 0.25 | 0.5 | 1.5 | 0.2 | 0.05 | 0.050 |
| Example 21 | | | | | | | | |
| Preparation | 0.5 | 0.9 | 0.25 | 0.5 | 1.5 | 0.2 | 0.05 | 0.070 |
| Example 22 | | | | | | | | |
| Preparation | 0.5 | 0.9 | 0.25 | 0.5 | 1.5 | 0.2 | 0.05 | 0.100 |
| Example 23 | | | | | | | | |
| Preparation | 0.5 | 0.9 | 0.25 | 0.5 | 1.5 | 0.2 | 0.05 | 0.300 |
| Example 24 | | | | | | | | |
| Preparation | 0.5 | 0.9 | 0.25 | 0.5 | 1.5 | 0.2 | 0.05 | 0.500 |
| Example 25 | | | | | | | | |
| Preparation | 0.5 | 0.9 | 0.25 | 0.5 | 1.5 | 0.2 | 0.05 | 0.700 |
| Example 26 | | | | | | | | |
| Preparation | 0.5 | 0.9 | 0.25 | 0.5 | 1.5 | 0.2 | 0.05 | 1.000 |
| Example 27 | | | | | | | | |
| Preparation | 0.5 | 0.9 | 0.25 | 0.5 | 1.5 | 0.2 | 0.05 | 0.0 |
| Example 28 | | | | | | | | |
| Preparation | 0.5 | 0.9 | 0.25 | 0.5 | 1.5 | 0.2 | 0.05 | 2.0 |
| Example 29 | | | | | | | | |
| Preparation | 0.5 | 0.9 | 0.25 | 0.5 | 1.5 | 0.2 | 0.05 | 3.0 |
| Example 30 | | | | | | | | |
| Preparation | 0.5 | 0.9 | 0.25 | 0.5 | 1.5 | 0.2 | 0.05 | 5.0 |
| Example 31 | | | | | | | | |
| Preparation | 0.5 | 0.9 | 0.25 | 0.5 | 1.5 | 0.2 | 0.05 | 7.0 |
| Example 32 | | | | | | | | |
| Preparation | 0.5 | 0.9 | 0.25 | 0.5 | 1.5 | 0.2 | 0.05 | 9.0 |
| Example 33 | | | | | | | | |
| Preparation | 0.5 | 0.9 | 0.25 | 0.5 | 1.5 | 0.2 | 0.05 | 10.0 |
| Example 34 | | | | | | | | |
| Preparation | 1 | 0.9 | 0.15 | 0.7 | 1 | 0.1 | 0.2 | 0.1 |
| Example 35 | | | | | | | | |
| Preparation | 0.90 | 0.9 | 0.15 | 0.7 | 1 | 0.1 | 0.2 | 0.1 |
| Example 36 | | | | | | | | |
| Preparation | 0.80 | 0.9 | 0.15 | 0.7 | 1 | 0.1 | 0.2 | 0.1 |
| Example 37 | | | | | | | | |
| Preparation | 0.70 | 0.9 | 0.15 | 0.7 | 1 | 0.1 | 0.2 | 0.1 |
| Example 38 | | | | | | | | |
| Preparation | 0.60 | 0.9 | 0.15 | 0.7 | 1 | 0.1 | 0.2 | 0.1 |
| Example 39 | | | | | | | | |
| Preparation | 0.50 | 0.9 | 0.15 | 0.7 | 1 | 0.1 | 0.2 | 0.1 |
| Example 40 | | | | | | | | |
| Preparation | 0.30 | 0.9 | 0.15 | 0.7 | 1 | 0.1 | 0.2 | 0.1 |
| Example 41 | | | | | | | | |
| Preparation | 0.25 | 0.9 | 0.15 | 0.7 | 1 | 0.1 | 0.2 | 0.1 |
| Example 42 | | | | | | | | |
| Preparation | 0.10 | 0.9 | 0.15 | 0.7 | 1 | 0.1 | 0.2 | 0.1 |
| Example 43 | | | | | | | | |
| Preparation | 0.0010 | 0.9 | 0.15 | 0.7 | 1 | 0.1 | 0.2 | 0.1 |
| Example 44 | | | | | | | | |
| Preparation | 1.2 | 0.9 | 0.15 | 0.7 | 1 | 0.1 | 0.2 | 0.1 |
| Example 45 | | | | | | | | |
| Preparation | 0.25 | 0.9 | 0.5 | 2 | 2 | 1 | 0.5 | 0.1 |
| Example 46 | | | | | | | | |
| Preparation | 0.30 | 0.9 | 0.5 | 2 | 2 | 1 | 0.5 | 0.1 |
| Example 47 | | | | | | | | |
| Preparation | 0.35 | 0.9 | 0.5 | 2 | 2 | 1 | 0.5 | 0.1 |
| Example 48 | | | | | | | | |
| Preparation | 0.40 | 0.9 | 0.5 | 2 | 2 | 1 | 0.5 | 0.1 |
| Example 49 | | | | | | | | |
| Preparation | 0.45 | 0.9 | 0.5 | 2 | 2 | 1 | 0.5 | 0.1 |
| Example 50 | | | | | | | | |
| Preparation | 0.50 | 0.9 | 0.5 | 2 | 2 | 1 | 0.5 | 0.1 |
| Example 51 | | | | | | | | |
| Preparation | 0.10 | 0.9 | 0.5 | 2 | 2 | 1 | 0.5 | 0.1 |
| Example 52 | | | | | | | | |
| Preparation | 0.20 | 0.9 | 0.5 | 2 | 2 | 1 | 0.5 | 0.1 |
| Example 53 | | | | | | | | |
| Preparation | 0.23 | 0.9 | 0.5 | 2 | 2 | 1 | 0.5 | 0.1 |
| Example 54 | | | | | | | | |
| Preparation | 0.53 | 0.9 | 0.5 | 2 | 2 | 1 | 0.5 | 0.1 |
| Example 55 | | | | | | | | |
| Preparation | 0.60 | 0.9 | 0.5 | 2 | 2 | 1 | 0.5 | 0.1 |
| Example 56 | | | | | | | | |
| Preparation | 0.70 | 0.9 | 0.5 | 2 | 2 | 1 | 0.5 | 0.1 |
| Example 57 | | | | | | | | |
| Preparation | 0.80 | 0.9 | 0.5 | 2 | 2 | 1 | 0.5 | 0.1 |
| Example 58 | | | | | | | | |
| Preparation | 0.90 | 0.9 | 0.5 | 2 | 2 | 1 | 0.5 | 0.1 |
| Example 59 | | | | | | | | |
| Preparation | 1.00 | 0.9 | 0.5 | 2 | 2 | 1 | 0.5 | 0.1 |
| Example 60 | | | | | | | | |
| Preparation | 0.25 | 0.5 | 0.15 | 2 | 1 | 1 | 0.5 | 0.1 |
| Example 61 | | | | | | | | |
| Preparation | 0.25 | 0.5 | 0.18 | 2 | 1 | 1 | 0.5 | 0.1 |
| Example 62 | | | | | | | | |
| Preparation | 0.25 | 0.5 | 0.20 | 2 | 1 | 1 | 0.5 | 0.1 |
| Example 63 | | | | | | | | |
| Preparation | 0.25 | 0.5 | 0.23 | 2 | 1 | 1 | 0.5 | 0.1 |
| Example 64 | | | | | | | | |
| Preparation | 0.25 | 0.5 | 0.25 | 2 | 1 | 1 | 0.5 | 0.1 |
| Example 65 | | | | | | | | |
| Preparation | 0.25 | 0.5 | 0.10 | 2 | 1 | 1 | 0.5 | 0.1 |
| Example 66 | | | | | | | | |
| Preparation | 0.25 | 0.5 | 0.30 | 2 | 1 | 1 | 0.5 | 0.1 |
| Example 67 | | | | | | | | |
| Preparation | 0.25 | 0.5 | 0.5 | 2 | 1 | 1 | 0.5 | 0.1 |
| Example 68 | | | | | | | | |
| Preparation | 0.25 | 0.5 | 0.7 | 2 | 1 | 1 | 0.5 | 0.1 |
| Example 69 | | | | | | | | |
| Preparation | 0.25 | 0.5 | 1 | 2 | 1 | 1 | 0.5 | 0.1 |
| Example 70 | | | | | | | | |
| Preparation | 0.5 | 0.80 | 0.15 | 2 | 2 | 1 | 0.5 | 0.1 |
| Example 71 | | | | | | | | |
| Preparation | 0.5 | 0.85 | 0.15 | 2 | 2 | 1 | 0.5 | 0.1 |
| Example 72 | | | | | | | | |
| Preparation | 0.5 | 0.90 | 0.15 | 2 | 2 | 1 | 0.5 | 0.1 |
| Example 73 | | | | | | | | |
| Preparation | 0.5 | 0.95 | 0.15 | 2 | 2 | 1 | 0.5 | 0.1 |
| Example 74 | | | | | | | | |
| Preparation | 0.5 | 1.00 | 0.15 | 2 | 2 | 1 | 0.5 | 0.1 |
| Example 75 | | | | | | | | |
| Preparation | 0.5 | 0.10 | 0.15 | 2 | 2 | 1 | 0.5 | 0.1 |
| Example 76 | | | | | | | | |
| Preparation | 0.5 | 0.30 | 0.15 | 2 | 2 | 1 | 0.5 | 0.1 |
| Example 77 | | | | | | | | |
| Preparation | 0.5 | 0.50 | 0.15 | 2 | 2 | 1 | 0.5 | 0.1 |
| Example 78 | | | | | | | | |
| Preparation | 0.5 | 0.70 | 0.15 | 2 | 2 | 1 | 0.5 | 0.1 |
| Example 79 | | | | | | | | |
| Preparation | 0.5 | 1.20 | 0.15 | 2 | 2 | 1 | 0.5 | 0.1 |
| Example 80 | | | | | | | | |
| Preparation | 0.5 | 1.50 | 0.15 | 2 | 2 | 1 | 0.5 | 0.1 |
| Example 81 | | | | | | | | |
| Preparation | 0.5 | 2.00 | 0.15 | 2 | 2 | 1 | 0.5 | 0.1 |
| Example 82 | | | | | | | | |
| Preparation | 0.5 | 3.00 | 0.15 | 2 | 2 | 1 | 0.5 | 0.1 |
| Example 83 | | | | | | | | |

¹⁾ Hydrogen peroxide
²⁾ Ammonium bifluoride
³⁾ Aminotetrazole
⁴⁾ Iminodiacetic acid
⁵⁾ Triethylene glycol
⁶⁾ Ammonium monophosphate
⁷⁾ Ammonium acetate
⁸⁾ L-pyroglutamic acid

TABLE 2

| | | Fluorine- | Nitrogen- | Carboxylic | Glycol- | | | |
|---|---|---|---|---|---|---|---|---|
| | Hydrogen | based | based cyclic | acid-based | based | | Acetate | Amino acid |
| | peroxide | compound ²⁾ | compound ³⁾ | compound ⁴⁾ | compound ⁵⁾ | Phosphate ⁶⁾ | salt ⁷⁾ | derivative ⁸⁾ |
| Comparative | 0.00 | 0.9 | 0.5 | 2 | 2 | 1 | 0.5 | 0.1 |
| Preparation | | | | | | | | |
| Example 1 | | | | | | | | |
| Comparative | 0.0001 | 0.9 | 0.15 | 0.7 | 1 | 0.1 | 0.2 | 0.1 |
| Preparation | | | | | | | | |
| Example 2 | | | | | | | | |
| Comparative | 30 | 0.9 | 0.15 | 0.7 | 1 | 0.1 | 0.2 | 0.1 |
| Preparation | | | | | | | | |
| Example 3 | | | | | | | | |
| Comparative | 25 | 0.9 | 0.15 | 0.7 | 1 | 0.1 | 0.2 | 0.1 |
| Preparation | | | | | | | | |
| Example 4 | | | | | | | | |
| Comparative | 20 | 0.9 | 0.15 | 0.7 | 1 | 0.1 | 0.2 | 0.1 |
| Preparation | | | | | | | | |
| Example 5 | | | | | | | | |
| Comparative | 15 | 0.9 | 0.15 | 0.7 | 1 | 0.1 | 0.2 | 0.1 |
| Preparation | | | | | | | | |
| Example 6 | | | | | | | | |
| Comparative | 10 | 0.9 | 0.15 | 0.7 | 1 | 0.1 | 0.2 | 0.1 |
| Preparation | | | | | | | | |
| Example 7 | | | | | | | | |
| Comparative | 5 | 0.9 | 0.15 | 0.7 | 1 | 0.1 | 0.2 | 0.1 |
| Preparation | | | | | | | | |
| Example 8 | | | | | | | | |
| Comparative | 0.25 | 0.5 | 2 | 2 | 1 | 1 | 0.5 | 0.1 |
| Preparation | | | | | | | | |
| Example 9 | | | | | | | | |
| Comparative | 0.5 | 0.00 | 0.15 | 2 | 2 | 1 | 0.5 | 0.1 |
| Preparation | | | | | | | | |
| Example 10 | | | | | | | | |

¹⁾ Hydrogen peroxide
²⁾ Ammonium bifluoride
³⁾ Aminotetrazole
⁴⁾ Iminodiacetic acid
⁵⁾ Triethylene glycol
⁶⁾ Ammonium monophosphate
⁷⁾ Ammonium acetate
⁸⁾ L-pyroglutamic acid

### Experimental Example

### Metal Concentration in Etchant for Confirmation of Cumulative Number of Substrates Treated

Titanium powder was added to the etchant compositions shown in Table 1 and Table 2 above to obtain etchants (Examples 1 to 83 and Comparative Examples 1 to 10) having the metal concentrations shown in Table 3 and Table 4 below.

Ti-deposited substrates (2×2 cm²) were etched with the etchants having the metal concentrations shown in Table 3 and Table 4 below, and then the etching time of the deposited Ti layer was measured. At this time, the etching time of the Ti layer was based on the etching endpoint detection (EPD) of the Ti layer detected by the naked eye.

Regarding the cumulative number of substrates treated, if the time calculated by “the etching time measured using a contaminated etchant-the time measured using an Uncontaminated etchant without titanium powder added” was 1 second or more, it was determined that the etching performance was not maintained. The maximum metal concentration value at which the etching performance was maintained was recorded. It was determined that the cumulative number of substrates treated increased as the contamination level (i.e., metal concentration) of the etchant, at which the etching performance was maintained, increased.

### Measurement of Etch Rate (E/R)

Ti-deposited substrates (2×2 cm²) were etched with the etchants (Examples 1 to 83 and Comparative Examples 1 to 10) having the metal concentrations shown in Table 3 and Table 4 below, and then the etching time of the deposited Ti layer was measured. At this time, the etching time of the Ti layer was based on the etching endpoint detection (EPD) of the Ti layer detected by the naked eye. The etch rate (E/R) was calculated by dividing the thickness of the Ti layer etched by the etching time (EPD), and the results are shown in Tables 3 and 4 below.

### Measurement of Undercut

Cu/Ti films were etched with the etchants having the metal concentrations shown in Tables 3 and 4 below. After completion of the etching, the substrates were washed and then dried, and the etching profiles were observed (after cutting a cross-section of the substrate, the cut portion was observed) using an FIB-SEM (continuous ion beam-differential scanning microscope). The results are shown in Tables 3 and 4 below.

As a criterion for measuring the undercut, the extent of penetration from the copper layer to the titanium layer in the bilayer (Cu/Ti film) under the copper plating layer was measured. If the undercut was 150 nm or less on average on both sides, it was marked as X, and if the undercut was more than 150 nm, it was marked as ○.

### Cu Damage

Cu/Ti films were etched with the etchants having the metal concentrations shown in Tables 3 and 4 below, and the results are shown in Tables 3 and 4 below.

Cu damage was calculated based on the substrate thickness (thickness before etching-thickness after etching/etching time). Based on the above measurement method, evaluation was performed according to the following criteria. ⊚: Cu damage of 1 or more to less than 5 nm/min; ○: Cu damage of 5 nm/min or more to less than 10 nm/min; Δ: Cu damage of 10 or more to less than 15 nm/min; and X: Cu damage of 15 nm/min or more.

TABLE 3

| | Metal concentration | E/R | | Cu damage |
|---|---|---|---|---|
| | (ppm) | (nm/min) | Undercut | (nm/min) |
| Example 1 | 0 | 70 | X | ⊚ |
| Example 2 | 150 | 70 | X | ⊚ |
| Example 3 | 300 | 70 | X | ⊚ |
| Example 4 | 500 | 60 | X | ⊚ |
| Example 5 | 0 | 60 | ◯ | ◯ |
| Example 6 | 150 | 65 | ◯ | ◯ |
| Example 7 | 300 | 50 | X | ◯ |
| Example 8 | 500 | 55 | X | ◯ |
| Example 9 | 0 | 50 | ◯ | ◯ |
| Example 10 | 150 | 45 | ◯ | ◯ |
| Example 11 | 300 | 40 | ◯ | ◯ |
| Example 12 | 500 | 35 | ◯ | ◯ |
| Example 13 | 0 | 40 | ◯ | ◯ |
| Example 14 | 150 | 35 | ◯ | ◯ |
| Example 15 | 300 | 30 | ◯ | ◯ |
| Example 16 | 500 | 25 | ◯ | ◯ |
| Example 17 | 450 | 70 | X | ⊚ |
| Example 18 | 455 | 70 | X | ⊚ |
| Example 19 | 460 | 70 | X | ⊚ |
| Example 20 | 470 | 70 | X | ⊚ |
| Example 21 | 480 | 70 | X | ⊚ |
| Example 22 | 490 | 70 | X | ⊚ |
| Example 23 | 500 | 70 | X | ⊚ |
| Example 24 | 500 | 70 | X | ⊚ |
| Example 25 | 500 | 70 | X | ⊚ |
| Example 26 | 500 | 70 | X | ⊚ |
| Example 27 | 500 | 70 | X | ⊚ |
| Example 28 | 10 | 70 | X | ◯ |
| Example 29 | 500 | 70 | X | ◯ |
| Example 30 | 500 | 70 | X | ◯ |
| Example 31 | 500 | 70 | X | ◯ |
| Example 32 | 500 | 70 | X | ◯ |
| Example 33 | 500 | 70 | X | ◯ |
| Example 34 | 500 | 70 | X | ◯ |
| Example 35 | 500 | 80 | X | ◯ |
| Example 36 | 500 | 78 | X | ⊚ |
| Example 37 | 500 | 76 | X | ⊚ |
| Example 38 | 500 | 75 | X | ⊚ |
| Example 39 | 500 | 74 | X | ⊚ |
| Example 40 | 500 | 73 | X | ⊚ |
| Example 41 | 500 | 72 | X | ⊚ |
| Example 42 | 500 | 70 | X | ⊚ |
| Example 43 | 500 | 68 | X | ⊚ |
| Example 44 | 500 | 65 | X | ⊚ |
| Example 45 | 500 | 100 | ◯ | ◯ |
| Example 46 | 500 | 60 | X | ⊚ |
| Example 47 | 500 | 62 | X | ⊚ |
| Example 48 | 500 | 64 | X | ⊚ |
| Example 49 | 500 | 66 | X | ⊚ |
| Example 50 | 500 | 68 | X | ⊚ |
| Example 51 | 500 | 70 | X | ⊚ |
| Example 52 | 500 | 50 | ◯ | ⊚ |
| Example 53 | 500 | 55 | ◯ | ⊚ |
| Example 54 | 500 | 55 | ◯ | ⊚ |
| Example 55 | 500 | 80 | ◯ | ⊚ |
| Example 56 | 500 | 80 | ◯ | ⊚ |
| Example 57 | 500 | 90 | ◯ | ⊚ |
| Example 58 | 500 | 100 | ◯ | ⊚ |
| Example 59 | 500 | 110 | ◯ | ⊚ |
| Example 60 | 500 | 120 | ◯ | ⊚ |
| Example 61 | 500 | 70 | X | X |
| Example 62 | 500 | 70 | X | X |
| Example 63 | 500 | 70 | X | X |
| Example 64 | 500 | 70 | X | X |
| Example 65 | 500 | 70 | X | X |
| Example 66 | 500 | 80 | X | X |
| Example 67 | 500 | 60 | X | X |
| Example 68 | 500 | 50 | X | X |
| Example 69 | 500 | 45 | X | X |
| Example 70 | 500 | 40 | X | X |
| Example 71 | 500 | 70 | X | X |
| Example 72 | 500 | 70 | X | X |
| Example 73 | 500 | 70 | X | X |
| Example 74 | 500 | 70 | X | X |
| Example 75 | 500 | 70 | X | X |
| Example 76 | 500 | 50 | X | X |
| Example 77 | 500 | 55 | X | X |
| Example 78 | 500 | 60 | X | X |
| Example 79 | 500 | 65 | X | X |
| Example 80 | 500 | 80 | X | X |
| Example 81 | 500 | 90 | X | X |
| Example 82 | 500 | 100 | X | X |
| Example 83 | 500 | 110 | X | X |

TABLE 4

| | Metal concentration | E/R | | Cu damage |
|---|---|---|---|---|
| | (ppm) | (nm/min) | Undercut | (nm/min) |
| Comparative | 500 | 40 | ◯ | ⊚ |
| Example 1 | | | | |
| Comparative | 500 | 90 | X | ⊚ |
| Example 2 | | | | |
| Comparative | 500 | 84 | ◯ | X |
| Example 3 | | | | |
| Comparative | 500 | 85 | ◯ | X |
| Example 4 | | | | |
| Comparative | 500 | 82 | ◯ | X |
| Example 5 | | | | |
| Comparative | 500 | 79 | ◯ | X |
| Example 6 | | | | |
| Comparative | 500 | 77 | ◯ | Δ |
| Example 7 | | | | |
| Comparative | 500 | 75 | ◯ | Δ |
| Example 8 | | | | |
| Comparative | 500 | 35 | ◯ | Δ |
| Example 9 | | | | |
| Comparative | 500 | 45 | ◯ | ◯ |
| Example 10 | | | | |

Referring to Examples 1 to 16, it was confirmed that, when L-pyroglutamic acid, a pyrrolidone derivative among amino acid derivatives, was used, the etch rate was able to be maintained at ±70 nm/min even when the contamination level increased, and the undercut of the lower layer and Cu damage of the upper layer was able to be reduced, indicating that the etching profile was excellent.

Referring to Examples 17 to 34, it was confirmed that, when the amino acid derivative was included in an amount of 0.001 to 1 wt %, the etch rate was able to be maintained at 70 nm/min, and the undercut of the lower layer and Cu damage of the upper layer was able to be reduced, indicating that the etching profile was excellent.

Referring to Examples 35 to 45 and Comparative Examples 1 to 8, it was confirmed that, when hydrogen peroxide was included in an amount of 0.001 to 4 wt %, particularly, 1 wt % or less, the undercut of the lower layer and Cu damage of the upper layer were low.

Referring to Examples 46 to 60, it was confirmed that, when the weight ratio between hydrogen peroxide and the fluorine-based compound was adjusted within a specific range, the etch rate was able to be maintained at ±70 nm/min, and the undercut of the lower layer and Cu damage of the upper layer were low.

Referring to Examples 61 to 70, it was confirmed that, when the weight ratio between hydrogen peroxide and the nitrogen-based cyclic compound was 1:0.1 to 1.5, the etch rate was able to be maintained at 60 to 70 nm/min, and the undercut of the lower layer was able to be reduced.

Referring to Examples 71 to 83 and Comparative Examples 9 and 10, it was confirmed that, when the weight ratio between the fluorine-based compound and the nitrogen-based cyclic compound was 1:0.01 to 3, the undercut of the lower layer was able to be reduced.

Although the present disclosure has been described above with reference to the embodiments, the present disclosure is not limited to the embodiments disclosed herein, and it is obvious that various modifications can be made by those skilled in the art without departing from the scope of the technical idea of the present disclosure. In addition, even though the effect according to the configuration of the present disclosure has not been explicitly described while describing the embodiments of the present disclosure, it is obvious that effects that can be predicted by the corresponding configuration should also be recognized.

What is claimed is:

1. An etchant composition comprising:
hydrogen peroxide;
a carboxylic acid-based compound;
a fluorine-based compound; and
a nitrogen-based cyclic compound,
wherein the hydrogen peroxide is included in an amount of 0.001 to 4 wt %.

2. The etchant composition of claim 1, comprising 0.1 to 5 wt % of the carboxylic acid-based compound; 0.01 to 2 wt % of the fluorine-based compound, 0.001 to 1 wt % of the nitrogen-based cyclic compound, and the balance of water.

3. The etchant composition of claim 1, further comprising at least one of 1 to 5 wt % of a glycol-based compound, 0.01 to 5 wt % of a phosphate compound, 0.001 to 2 wt % of an acetate salt, or 0.001 to 1 wt % of an amino acid derivative.

4. The etchant composition of claim 1, wherein the glycol-based compound is at least one selected from the group consisting of ethylene glycol, diethylene glycol, triethylene glycol, polyethylene glycol, and any combinations thereof,
wherein the phosphate compound is at least one selected from the group consisting of ammonium monophosphate, sodium monophosphate, sodium diphosphate, ammonium diphosphate, sodium triphosphate, ammonium triphosphate, and any combinations thereof,
wherein the acetate salt is at least one selected from the group consisting of ammonium acetate, sodium acetate, potassium acetate, and any combinations thereof, and
wherein the amino acid derivative is at least one selected from the group consisting of L-pyroglutamic acid, sodium pyrrolidone carboxylic acid, zinc pyrrolidone carboxylic acid, and any combinations thereof.

5. The etchant composition of claim 1, wherein a weight ratio between the hydrogen peroxide and the fluorine-based compound is 1:0.01 to 1:9.

6. The etchant composition of claim 1, wherein a weight ratio between the hydrogen peroxide and the nitrogen-based cyclic compound is 1:0.1 to 1:1.5.

7. The etchant composition of claim 1, wherein the carboxylic acid-based compound is at least one selected from the group consisting of iminodiacetic acid, oxalic acid, acetic acid, formic acid, acrylic acid, lactic acid, amino acids, propionic acid, oleic acid, benzoic acid, salicylic acid, malic acid, and any combinations thereof,
wherein the fluorine-based compound is at least one selected from the group consisting of ammonium bifluoride (NH₄F·HF), ammonium fluoride (NH₄F), sodium bifluoride (NaHF₂), sodium fluoride (NaF), potassium bifluoride (HF₂K), potassium fluoride (KF), hydrofluoric acid (HF), and any combinations thereof.

8. The etchant composition of claim 1, wherein the nitrogen-based cyclic compound does not comprise alkyl and aryl groups.

9. The etchant composition of claim 8, wherein the nitrogen-based cyclic compound is at least one selected from the group consisting of benzotriazole, aminotetrazole, methyltetrazole, aminomercaptotriazole, and any combinations thereof.

10. The etchant composition of claim 1, wherein a metal concentration in the etchant composition is 500 ppm or less.

11. An etchant composition comprising:
hydrogen peroxide;
a carboxylic acid-based compound;
a fluorine-based compound; and
a nitrogen-based cyclic compound,
wherein a weight ratio between the fluorine-based compound and the nitrogen-based cyclic compound is 1:0.01 to 1:3.

12. The etchant composition of claim 11, comprising 0.1 to 5 wt % of the carboxylic acid-based compound; 0.01 to 2 wt % of the fluorine-based compound, 0.001 to 1 wt % of the nitrogen-based cyclic compound, and the balance of water.

13. The etchant composition of claim 11, further comprising at least one of 1 to 5 wt % of a glycol-based compound, 0.01 to 5 wt % of a phosphate compound, 0.001 to 2 wt % of an acetate salt, or 0.001 to 1 wt % of an amino acid derivative.

14. The etchant composition of claim 11, wherein the glycol-based compound is at least one selected from the group consisting of ethylene glycol, diethylene glycol, triethylene glycol, polyethylene glycol, and any combinations thereof,
wherein the phosphate compound is at least one selected from the group consisting of ammonium monophosphate, sodium monophosphate, sodium diphosphate, ammonium diphosphate, sodium triphosphate, ammonium triphosphate, and any combinations thereof,
wherein the acetate salt is at least one selected from the group consisting of ammonium acetate, sodium acetate, potassium acetate, and any combinations thereof, and
wherein the amino acid derivative is at least one selected from the group consisting of L-pyroglutamic acid, sodium pyrrolidone carboxylic acid, zinc pyrrolidone carboxylic acid, and any combinations thereof.

15. The etchant composition of claim 11, wherein a weight ratio between the hydrogen peroxide and the fluorine-based compound is 1:0.01 to 1:9.

16. The etchant composition of claim 11, wherein a weight ratio between the hydrogen peroxide and the nitrogen-based cyclic compound is 1:0.1 to 1:1.5.

17. The etchant composition of claim 11, wherein the carboxylic acid-based compound is at least one selected from the group consisting of iminodiacetic acid, oxalic acid, acetic acid, formic acid, acrylic acid, lactic acid, amino acids, propionic acid, oleic acid, benzoic acid, salicylic acid, malic acid, and any combinations thereof,
wherein the fluorine-based compound is at least one selected from the group consisting of ammonium bifluoride (NH₄F·HF), ammonium fluoride (NH₄F), sodium bifluoride (NaHF₂), sodium fluoride (NaF), potassium bifluoride (HF₂K), potassium fluoride (KF), hydrofluoric acid (HF), and any combinations thereof.

18. The etchant composition of claim 11, wherein the nitrogen-based cyclic compound does not comprise alkyl and aryl groups.

19. The etchant composition of claim 18, wherein the nitrogen-based cyclic compound is at least one selected from the group consisting of benzotriazole, aminotetrazole, methyltetrazole, aminomercaptotriazole, and any combinations thereof.

20. The etchant composition of claim 11, wherein a metal concentration in the etchant composition is 500 ppm or less.
